(19) United States
(12) Patent Application Publication
(10) Pub. No.: US 2012/0305894 A1
(43) Pub. Date: Dec. 6, 2012

(54) BLUE PHOSPHORESCENT COMPOUND AND ORGANIC ELECTROLUMINESCENT DEVICE USING THE SAME

(76) Inventors: Do-Han Kim, Goyang-si (KR); Seung-Jae Lee, Goyang-si (KR); Jae-Han Bae, Seoul (KR); Dae-Wi Yoon, Paju-si (KR); In-Bum Song, Seoul (KR); Jung-Keun Kim, Seoul (KR); Jong-Kwan Bin, Paju-si (KR); Nam-Sung Cho, Daejeon (KR); Seog-Shin Kang, Goyang-si (KR); Joong-Hwan Yang, Gwangmyeong-si (KR)

(21) Appl. No.: 13/338,801

(22) Filed: Dec. 28, 2011

(30) Foreign Application Priority Data
Jun. 1, 2011 (KR) 10-2011-0052980

(51) Int. Cl. H01L 51/54; C07F 15/00

(52) U.S. Cl. 257/40; 546/4; 544/225; 257/E51.026

(57) ABSTRACT

Disclosed are a blue phosphorescent compound with a high color purity and a high efficiency, and an organic electroluminescent device using the same. The blue phosphorescent compound is represented by the following Formula:

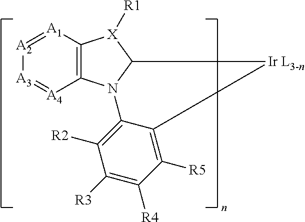

wherein R1 to R5 are each independently hydrogen (H), fluorine (F), chlorine (Cl), bromine (Br), a cyano group, a C1 to C6 alkyl group, a C1 to C6 alkoxy group, a C6 to C20 substituted or unsubstituted aromatic group, a C5 to C20 substituted or unsubstituted heterocyclic group, a C1 to C6 amine group, a C6 to C20 aromatic-substituted amine group, or a C5 to C20 heterocycle-substituted amine group, X is selected from nitrogen (N), oxygen (O), phosphorous (P) and sulfur (S) atoms, at least one of A1, A2, A3 and A4 is nitrogen (N), and the remaining are selected from hydrogen (H)-substituted carbon, and alkyl or alkoxy-substituted carbon, L is a monodentate or bidentate ligand and n is 1 to 3.

This application claims the priority and the benefit under 35 U.S.C. §119(a) on Korean Patent Application No. 10-2011-0052980, filed on Jun. 1, 2011, the entire contents of which are hereby incorporated by reference.

### BACKGROUND

1. Field of the Invention

The present disclosure relates to a blue phosphorescent compound. In particular, the present invention relates to a blue phosphorescent compound with a high color purity and a high efficiency and an organic electroluminescenct device using the same.

2. Discussion of the Related Art

Image display devices to display a variety of information on a screen are developed as major technology of the info-communication age with trends of thinner, more portability and higher performance. The recent development of an information-age society as well as an increase in the variety of demands placed upon display devices has brought about a great deal of research associated with flat panel display devices such as liquid crystal displays (LCDs), plasma display panels (PDPs), electroluminescent displays (ELDs), and field emission displays (FEDs).

Among these, organic electroluminescenct devices emit light, when electric charges are injected into an organic light-emitting layer formed between an electron injection electrode (cathode) and a hole injection electrode (anode), and electrons pair with holes and then decay.

The organic electroluminescenct device may be formed on flexible transparent substrates such as plastics, and has advantages of low drive voltage, low power consumption and excellent color reproduction, as compared to plasma display panels or inorganic electroluminescent (EL) displays.

The organic light-emitting layer emits red, green or blue depending on the compound contained in the light-emitting layer, and known organic compounds include 2,2-(diaryl)vinylphosphine compounds, compounds in which aryl is substituted in an end of a diphenyl anthracene structure and the like.

However, known organic compounds including the above compounds have insufficient lifespan, luminous efficacy, and brightness and, in particular, cannot realize phosphorescent materials which emit blue light and exhibit sufficient color purity and high efficiency and cannot thus realize displays capable of displaying the full range of natural colors.

Conventional organic electroluminescenct devices have the following problems.

In order to impart high efficiency to organic electroluminescenct devices, the light-emitting layer is made of a phosphorescent material alone, which can use triplet excitons for light emission. However, blue phosphorescent materials which have sufficiently high color purity suitable for use in organic electroluminescenct devices have not been developed to date. This is the most major obstacle in use of organic electroluminescent devices as next generation displays.

### BRIEF SUMMARY

A blue phosphorescent compound represented by the following Formula 1:

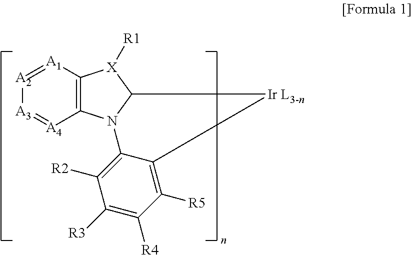

wherein R1 to R5 are each independently hydrogen (H), fluorine (F), chlorine (Cl), bromine (Br), a cyano group, a C1 to C6 alkyl group, a C1 to C6 alkoxy group, C6 to C20 substituted or unsubstituted aromatic group, a C5 to C20 substituted or unsubstituted heterocyclic group, a C1 to C6 amine group, a C6 to C20 aromatic-substituted amine group, or a C5 to C20 heterocycle-substituted amine group;

X is selected from nitrogen (N), oxygen (O), phosphorous (P) and sulfur (S) atoms;

at least one of A1, A2, A3 and A4 is nitrogen (N), and the remaining are selected from hydrogen (H)-substituted carbon, and alkyl or alkoxy-substituted carbon; and

L is a monodentate or bidentate ligand and n is 1 to 3.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and along with the description serve to explain the principle of the invention. In the drawings:

FIG. 1 is a sectional view illustrating an organic electroluminescent device; and

FIG. 2 is a graph showing UV and photoluminescence (PL) spectra of a blue phosphorescent compound according to an embodiment of the present invention.

### DETAILED DESCRIPTION OF THE DRAWINGS AND THE PRESENTLY PREFERRED EMBODIMENTS

Hereinafter, a blue phosphorescent compound and an organic electroluminescent device using the same according to an embodiment the present invention will be described in detail.

The blue phosphorescent compound of the present invention is represented by the following Formula 1.

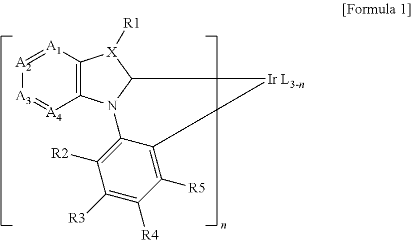

wherein R1 to R5 are each independently hydrogen (H), fluorine (F), chlorine (Cl), bromine (Br), a cyano group, a C1 to C6 alkyl group, a C1 to C6 alkoxy group, C6 or higher substituted or unsubstituted aromatic group, a C5 or higher substituted or unsubstituted heterocyclic group, a C1 to C6 amine group, a C6 or higher aromatic-substituted amine group, or a C5 or higher heterocycle-substituted amine group.

When R1 to R5 are each independently a C6 or higher substituted or unsubstituted aromatic group, a C5 or higher substituted or unsubstituted heterocyclic group, a C6 or higher aromatic-substituted amine group, or a C5 or higher heterocycle-substituted amine group, the maximum number of carbon atoms of the corresponding group is preferably C20.

The C1 to C6 alkyl group is selected from the group consisting of methyl, ethyl, n-propyl, i-propyl, n-butyl, i-butyl and t-butyl. The C1 to C6 alkoxy group is selected from the group consisting of methoxy, ethoxy, n-propoxy, i-propoxy, n-butoxy, i-butoxy and t-butoxy.

X is selected from nitrogen (N), oxygen (O), phosphorous (P) and sulfur (S) atoms.

In addition, at least one of A1, A2, A3 and A4 is nitrogen (N), and the remaining are selected from hydrogen (H)-substituted carbon, and an alkyl- or alkoxy-substituted carbon.

In addition, L is a monodentate or bidentate ligand and n is 1 to 3.

The blue compound of the present invention is an iridium compound which uses an N-heteroring-substituted carbene compound as a ligand, which is a blue phosphorescent compound which exhibits particularly high color purity and high efficiency based on the suggested structure. In particular, at least one of moieties of phenyl rings fused in imidazole of a carbene ligand is a nitrogen atom (N).

Meanwhile, the blue phosphorescent compound represented by Formula 1 is represented by one of the following compounds B1 to B7, but is not limited thereto.

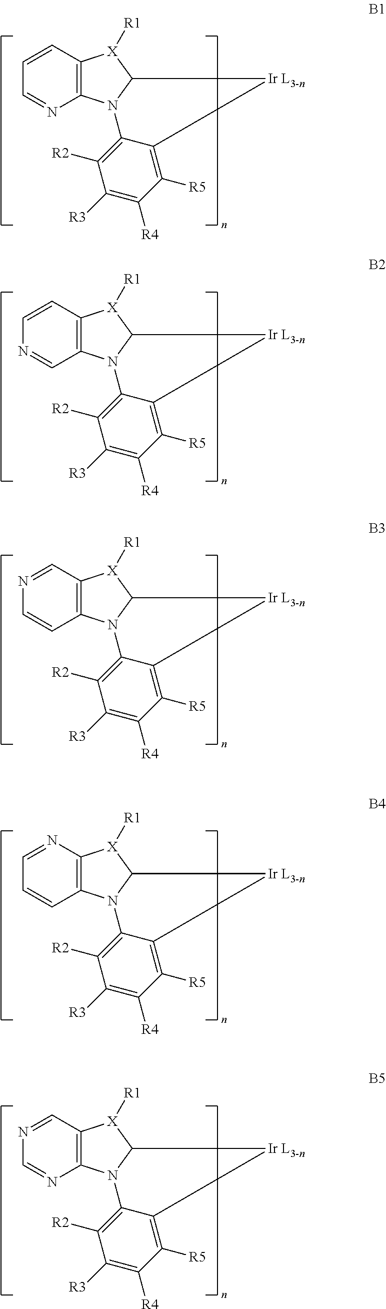

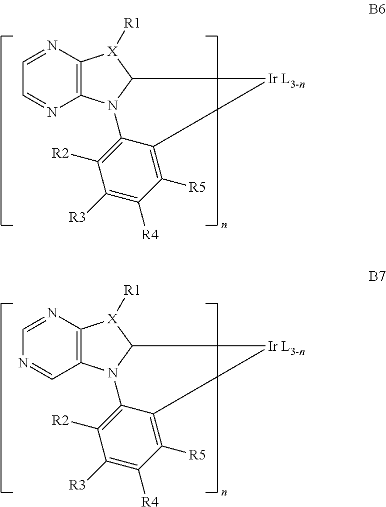

The exemplary compounds of B1 to B7 have a structure of Formula 1 in which one or two of A1 to A4 are substituted by nitrogen.

More preferably, the compound of Formula 1 may be represented by one of the following compounds BB1 to BB7. The compound is a compound in which X is a nitrogen atom (N) among the exemplary compounds of B1 to B7.

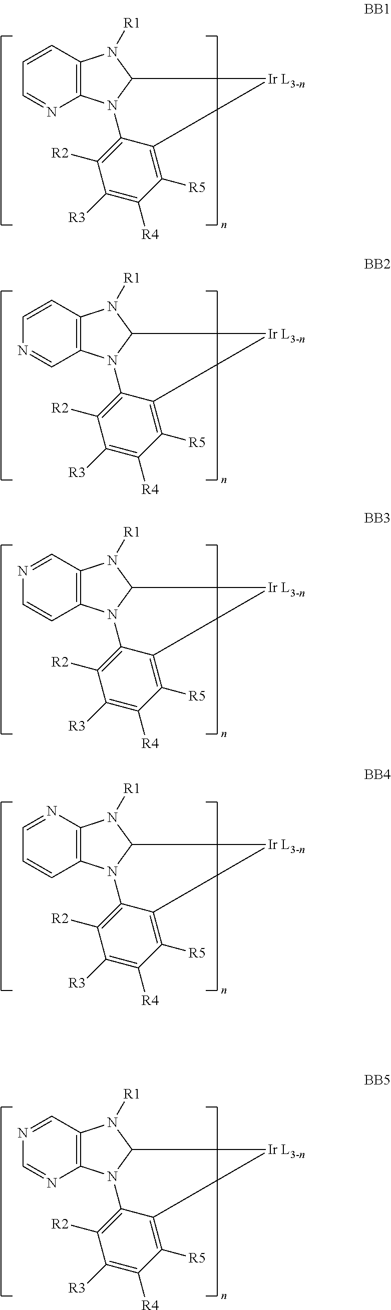

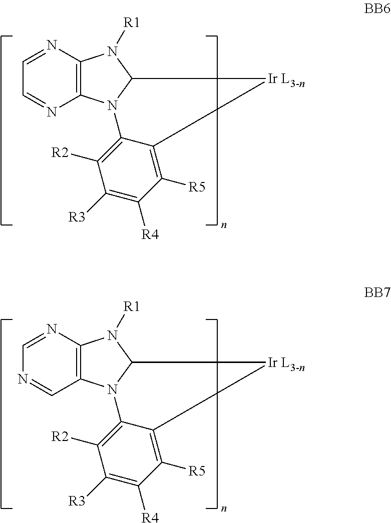

In addition, even more preferably, the compound of Formula 1 is a compound in which n is 3, like the following compounds BBB1 to BBB7.

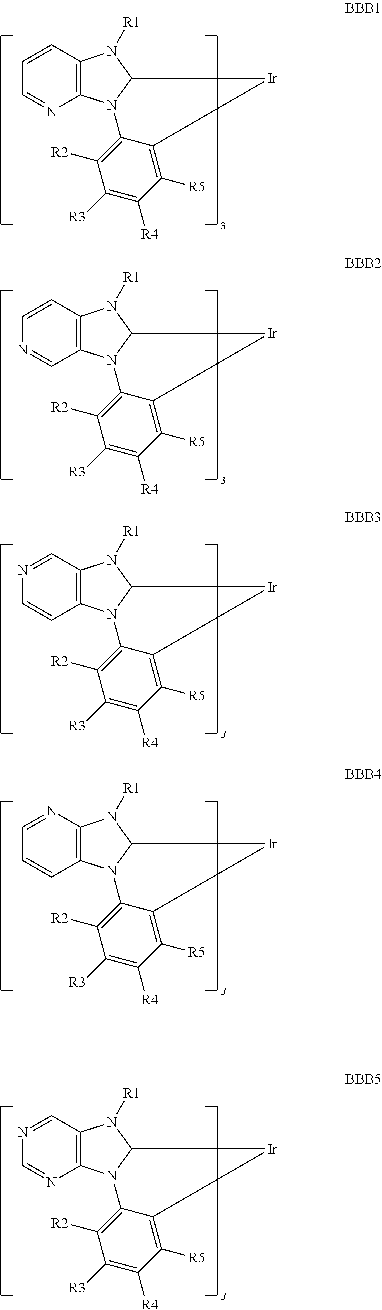

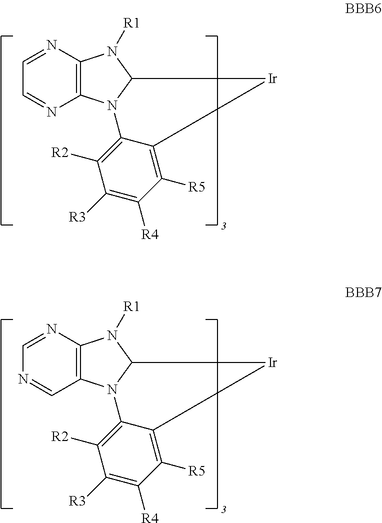

Meanwhile, the blue phosphorescent compound of the present invention is not limited to the compounds B1 to B7, or the compounds BB1 to BB7 or the compounds BBB1 to BBB7 and may be modified within the scope in which the conditions of Formula 1 are satisfied.

In addition, in the compounds specifically mentioned above, R1 to R5 are defined as in Formula 1. That is, R1 to R5 are each independently hydrogen (H), fluorine (F), chlorine (Cl), bromine (Br), a cyano group, a C1 to C6 alkyl group, a C1 to C6 alkoxy group, a C6 or higher substituted or unsubstituted aromatic group, a C5 or higher substituted or unsubstituted heterocyclic group, a C1 to C6 amine group, a C6 or higher aromatic-substituted amine group, or a C5 or higher heterocycle-substituted amine group.

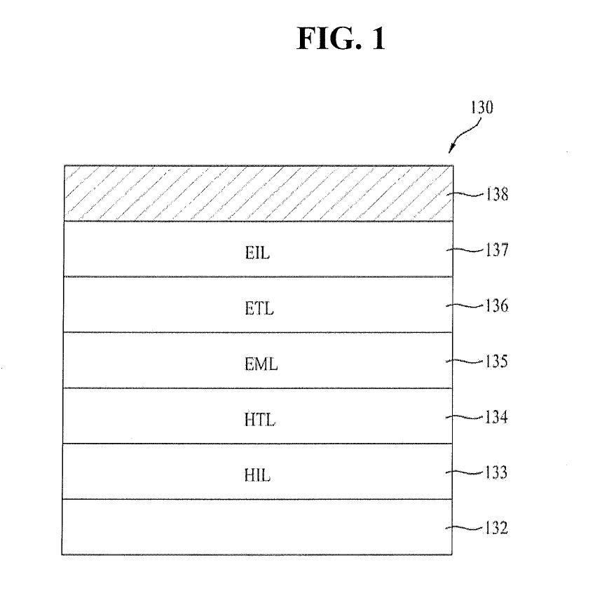

FIG. 1 is a view illustrating an organic electroluminescent device according to the present invention.

As shown in FIG. 1, the organic electroluminescent device 130 of the present invention includes an anode 132, a cathode 138 and an organic film interposed therebetween wherein the organic film contains a blue phosphorescent compound represented by Formula 1 above.

Specifically, the organic film is contained in a light-emitting layer (EML) 135 and the light-emitting layer 135 is formed by doping about 0.1 to about 50% by weight of the blue phosphorescent compound represented by Formula 1, with respect to the total weight of the light-emitting layer 135.

In addition, as shown in the drawing, the organic electroluminescent device 130 may further include a hole-injection layer (HIL) 133 and a hole transport layer (HTL) 134 arranged in this order between the anode 132 and the light-emitting layer 135, and an electron transport layer (ETL) 136 and an electron injection layer (EIL) 137 arranged in this order between the light-emitting layer 135 and the cathode 138.

Here, the hole-injection layer (HIL) 133 and the hole transport layer (HTL) 134 arranged in this order between the anode 132 and the light-emitting layer 135, and the electron transport layer (ETL) 136 and the electron injection layer (EIL) 137 arranged in this order between the light-emitting layer 135 and the cathode 138 may be omitted. In this case, the light-emitting layer may serve as a hole or electron transporting layer, or a hole or electron injection layer.

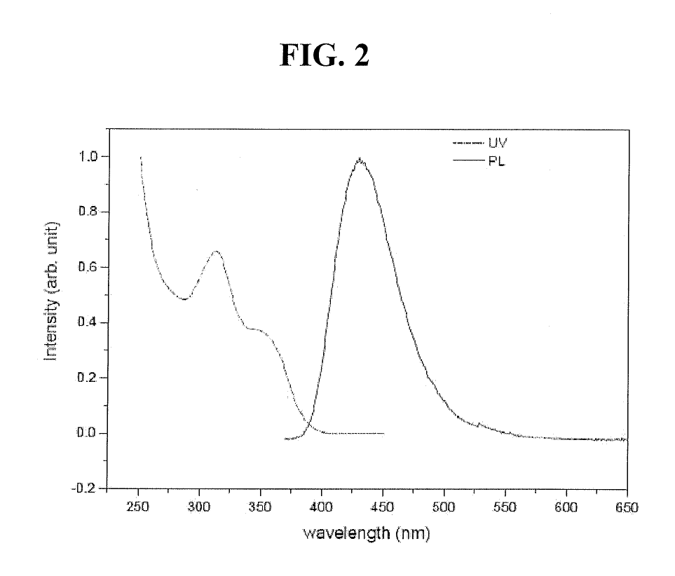

FIG. 2 is a graph showing UV and photoluminescence (PL) spectra of the blue phosphorescent compound of the present invention.

As shown in FIG. 2, in particular, the blue phosphorescent compound of the present invention has PL peak values at a wavelength of about 430 nm, which indicates that phosphorescent emission characteristics are observed within a wavelength range with a high blue color purity.

Among iridium complex compounds known to date, blue phosphorescent compounds exhibit PL peak values at a wavelength higher than about 450 nm or lower than 410 nm. Blue phosphorescent compounds (having PL peak values at a wavelength higher than 450 nm) have a problem of difficulty of full-color realization due to emission of green-like light when applied to displays. Blue phosphorescent compounds (having PL peak values at a wavelength lower than 410 nm) may have high color purity, but are matched to a near ultraviolet range having a considerably low visibility efficiency in a visibility curve, expressing visibility sensed by the eye, thus having a great efficiency difference as compared to materials emitting other colors of light due to considerably low efficiency. Accordingly, these materials are also unsuitable for application to displays.

Like phosphorescent compounds, compounds having a particularly large band gap have a problem of excessively low efficiency, when they have excessively low color purity. The blue phosphorescent compound of the present invention has PL peak values at about 430 nm to about 450 nm, an optimum wavelength which is suitable for emission of blue light and emits light with high color purity. As a result, it is possible to secure a wavelength range having inherent color purity of blue, reduce a band gap energy as compared to materials having PL peak values at a wavelength lower than 410 nm and thereby realize high efficiency. Accordingly, when an organic electroluminescent device is realized using a light-emitting layer using the blue phosphorescent compound of the present invention, the organic electroluminescent device can operate at a low power.

In addition, an organic electroluminescent device which includes a first light-emitting layer made of a blue phosphorescent compound and other light-emitting layers made of red and green phosphorescent materials in a stack structure can display a full range of natural colors.

In addition, an organic electroluminescent device including a light-emitting layer made of a blue phosphorescent compound may be used for image display displays, lighting systems and the like.

For example, the organic electroluminescent device may be used for televisions, cellular phones, notebook computers, digital cameras, display devices for vehicles and display devices for food and clothing stores.

Hereinafter, a method for synthesizing the blue phosphorescent compound will be described.

A method for synthesizing one example of BBB1, BBB1-E in which R1 is phenyl, and R2 to R5 are hydrogen-substituted carbon will be described.

### Synthesis Example

### 1) Synthesis of Ligand Precursor

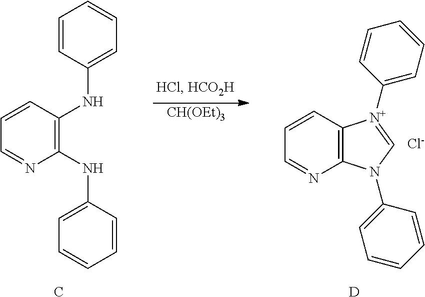

A mixed solution of 2.0 g (7.7 mmol) of N2,N3-diphenylpyridine-2,3-diamine (C), 0.75 ml of HCl, 5 drops of HCO2H, and 50 ml of CH(OEt)3 was stirred at 80° C. for 3 hours. After the reaction was completed, the reaction mixture was allowed to cool to room temperature and the resulting precipitate was filtered and washed with ethyl acetate and hexane to obtain 2.0 g (6.5 mmol, yield: 85%) of a precipitate D.

### 2) Synthesis of Iridium Compound

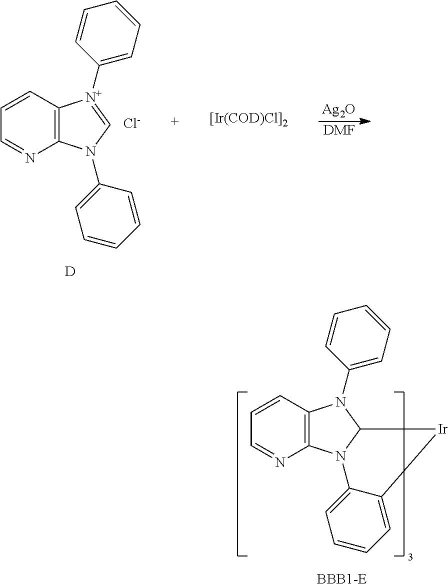

2.0 g (6.5 mmol) of an imidazolinium compound D, 0.67 g (1.0 mmol) of [Ir(COD)Cl]2, and 1.5 g (6.5 mmol) of Ag2O were added to 60 mL of DMF under a nitrogen atmosphere, followed by refluxing for 18 hours. After the reaction was completed, the resulting precipitate was filtered and the filtrate was concentrated under reduced pressure. The residue was purified by column chromatography to obtain a compound BBB1-E as a major isomer.

A method for fabricating an organic electroluminescent device using the blue phosphorescent compound according to the present invention will be described, but the present invention is not limited thereto.

First, an anode material (see 132 of FIG. 1) was deposited on a transparent substrate (not shown). A material for the anode is for example indium tin oxide (ITO).

Subsequently, a hole-injection layer (HIL) 133 was applied to the anode 132.

For example, 4,4′-bis[N-[4-{N,N-bis(3-methylphenyl)amino}phenyl]-N-phenylamino]biphenyl (DNTPD) was applied to a thickness of 10 to 30 nm as the hole-injection layer 133.

Subsequently, a hole transport layer (HTL) 134 is formed on the hole-injection layer 133. The hole transport layer 134 is formed by coating 4,4′-bis[N-(1-naphthyl)-N-phenylamino]-biphenyl (NPB) by deposition to a thickness of 30 to 60 nm.

Subsequently, a light-emitting layer 135 containing the blue phosphorescent compound represented by Formula 1 is formed. At this time, a dopant was added as necessary, during formation of the light-emitting layer.

Meanwhile, in addition to the light-emitting layer 135 composed of a blue phosphorescent compound, red light-emitting layers and green light-emitting layers in the form of a stack may be further formed. In this case, the red light-emitting layer and green light-emitting layer formed together with the light-emitting layer 135 constitute one pixel and realize a variety of grayscales. In addition, in this case, additional organic films may be further formed between the light-emitting layers.

For example, a green light-emitting layer may be formed by doping 1 to 3 wt % of N-methylquinacridone (MQD) as a dopant to Alq3 (8-droxyquinolatealuminum) to a thickness of about 300 Å.

As to a phosphorescent compound, a phosphorescent layer can be formed by doping about 5 to 10% of bis(2-phenylquinoline)(acetylacetonate)iridium (III) (Ir(phq)2(acac)) as a phosphorescent red dopant to bis(N-carbazolyl)biphenyl (CBP).

Subsequently, an electron transport layer (ETL) 136 and an electron injection layer (EIL) 137 are sequentially formed on the light-emitting layer 135. Tris(8-hydroxyquinolate) aluminum (Alq3) is generally used as the electron transport layer (136).

Subsequently, a cathode 138 is deposited on the electron injection layer 137 and finally a protective film (not shown) is further formed thereon. In this case, the protective film may be an organic film or a glass cap. At this time, the organic film may repeatedly alternate with an inorganic film.

In the light-emitting layer 135 of the organic electroluminescent device, electrons and holes injected from both electrodes 132 and 138 are recombined to form excitons. In order to prevent the formed excitons on the cathode 138 from being quenched, an exciton blocking layer which exhibits superior stability may be formed adjacent to the light-emitting layer.

The organic electroluminescent device using the blue phosphorescent compound can operate at low voltage and exhibits improved color purity and luminous efficacy.

In addition, the organic electroluminescent device exhibits low power consumption and long lifespan.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A blue phosphorescent compound represented by the following Formula 1: 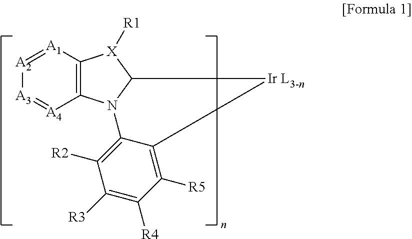
wherein R1 to R5 are each independently hydrogen (H), fluorine (F), chlorine (Cl), bromine (Br), a cyano group, a C1 to C6 alkyl group, a C1 to C6 alkoxy group, C6 to C20 substituted or unsubstituted aromatic group, a C5 to C20 substituted or unsubstituted heterocyclic group, a C1 to C6 amine group, a C6 to C20 aromatic-substituted amine group, or a C5 to C20 heterocycle-substituted amine group;
X is selected from nitrogen (N), oxygen (O), phosphorous (P) and sulfur (S) atoms;
at least one of A1, A2, A3 and A4 is nitrogen (N), and the remaining are selected from hydrogen (H)-substituted carbon, and alkyl or alkoxy-substituted carbon; and
L is a monodentate or bidentate ligand and n is 1 to 3.

2. The blue phosphorescent compound according to claim 1, wherein the blue phosphorescent compound of Formula 1 is represented by one of the following compounds:

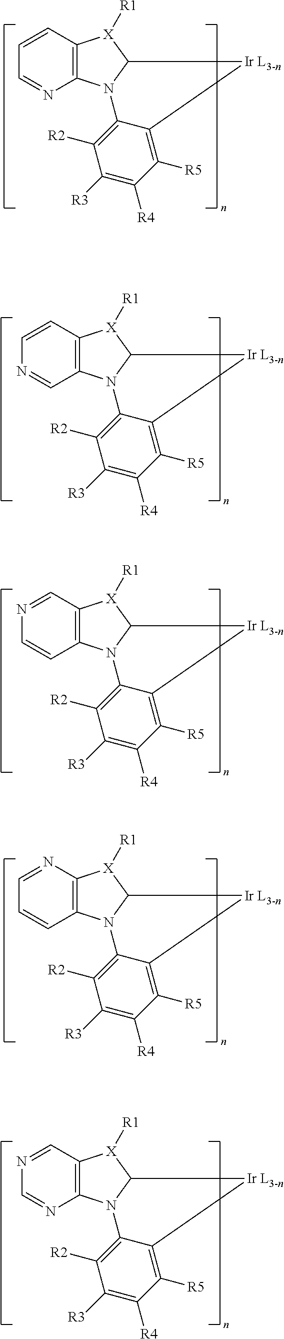

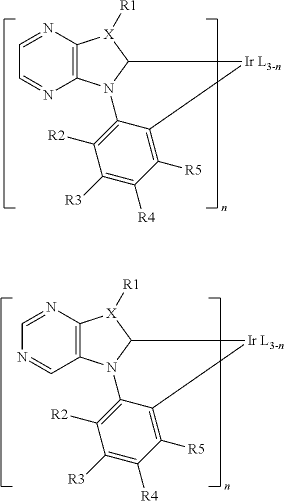

3. The blue phosphorescent compound according to claim 1, wherein the blue phosphorescent compound of Formula 1 is represented by one of the following compounds:

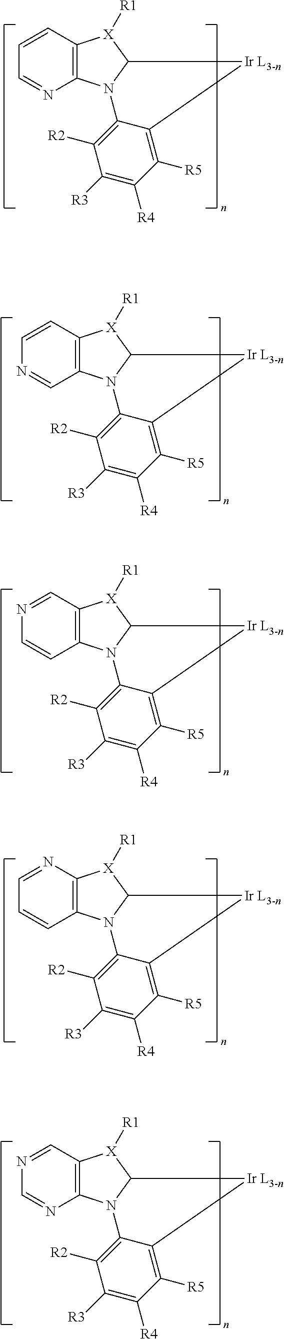

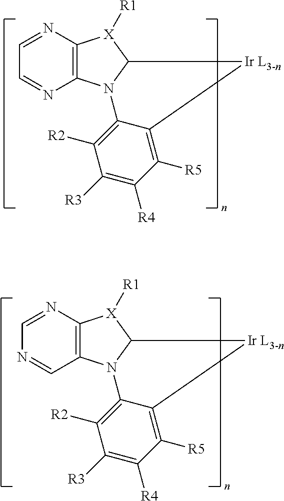

4. The blue phosphorescent compound according to claim 1, wherein the blue phosphorescent compound of Formula 1 is represented by one of the following compounds:

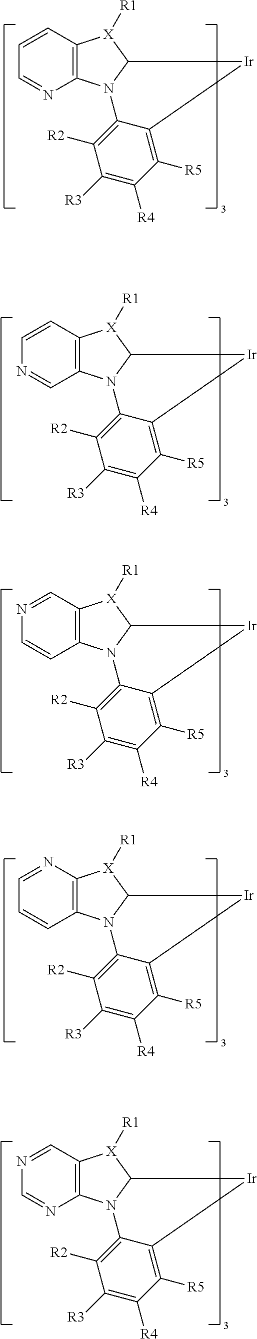

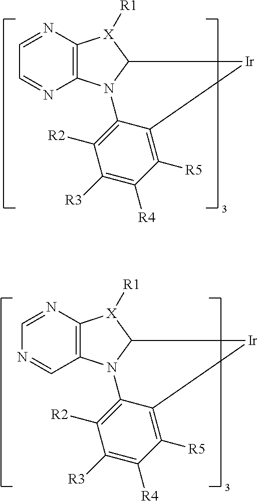

5. An organic electroluminescent device comprising an organic film interposed between an anode and a cathode,
wherein the organic film comprises a blue phosphorescent compound represented by Formula 1: 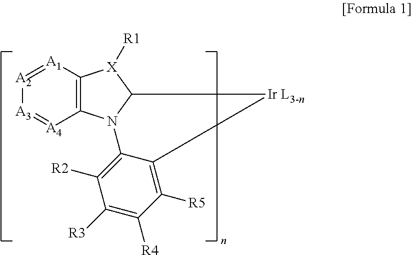
wherein R1 to R5 are each independently hydrogen (H), fluorine (F), chlorine (Cl), bromine (Br), a cyano group, a C1 to C6 alkyl group, a C1 to C6 alkoxy group, C6 to C20 substituted or unsubstituted aromatic group, a C5 to C20 substituted or unsubstituted heterocyclic group, a C1 to C6 amine group, a C6 to C20 aromatic-substituted amine group, or a C5 to C20 heterocycle-substituted amine group;
X is selected from nitrogen (N), oxygen (O), phosphorous (P) and sulfur (S) atoms;
at least one of A1, A2, A3 and A4 is nitrogen (N), and the remaining are selected from hydrogen (H)-substituted carbon, and alkyl or alkoxy-substituted carbon; and
L is a monodentate or bidentate ligand and n is 1 to 3.

6. The organic electroluminescent device according to claim 5, wherein the organic film is a light-emitting layer.

7. The organic electroluminescent device according to claim 6, wherein the blue phosphorescent compound represented by Formula 1 is doped in an amount of about 0.1 to about 50% by weight in the light-emitting layer.

8. The organic electroluminescent device according to claim 6, further comprising:
a hole-injection layer and a hole transport layer arranged in this order between the anode and the light-emitting layer; and
an electron transport layer and an electron injection layer arranged in this order between the light-emitting layer and the cathode.
